(19) United States
(12) Patent Application Publication
(10) Pub. No.: US 2025/0279330 A1
(43) Pub. Date: Sep. 4, 2025

(54) ENHANCED INTEGRATED CIRCUIT HEAT DISSIPATION USING INACTIVE METAL LINES

(71) Applicant: QUALCOMM Incorporated, San Diego, CA (US)

(72) Inventors: Hithesh Hassan LEPAKSHA, Hyderabad (IN); Darshan Kumar NANDANWAR, Bangalore (IN); Kartik Gunvantbhai DESAI, Savarkundla (IN)

(21) Appl. No.: 18/592,179

(22) Filed: Feb. 29, 2024

(51) Int. Cl. H01L 23/367; H01L 23/48; H01L 23/525; H01L 25/065

(52) U.S. Cl. CPC H01L 23/3677; H01L 23/481; H01L 23/5252; H01L 25/0657; H01L 2225/06541; H01L 2225/06589

(57) ABSTRACT

An electronic device includes one or more substrates carrying active circuitry; a heat sink structure; one or more thermal through-substrate vias (TTSVs) forming a first set of one or more thermally conductive paths between the one or more substrates and the heat sink structure; and one or more metallization lines disposed in the one or more substrates, wherein in a first mode of operation of the active circuitry, the one or more metallization lines carry active signals of the active circuitry, and in a second mode of operation of the active circuitry in which the one or more metallization lines do not carry active signals of the active circuitry, the one or more metallization lines are connected as heat-conductive branches forming a second set of one or more thermally conductive paths in thermal contact with the first set of one or more thermally conductive paths.

### FIELD OF DISCLOSURE

The present disclosure generally relates to integrated circuit technology, and more particularly, to thermal dissipation structures used to dissipate heat generated in integrated circuits.

### BACKGROUND

Integrated circuit (IC) technology has achieved great strides in advancing computing power through miniaturization of electrical components. An IC may be implemented in the form of an IC chip that has a set of circuits integrated thereon. In some implementations, one or more IC chips can be physically carried and protected by an IC package, where various power and signal nodes of the one or more IC chips can be electrically coupled to respective conductive terminals of the IC package via electrical paths formed in a package substrate of the IC package. Various packaging technologies can be found in many electronic devices, including processors, servers, radio frequency (RF) integrated circuits, etc. Advanced packaging and processing techniques can be used to implement complex devices, such as multi-electronic component devices and system-on-a-chip (SOC) devices, which may include multiple function blocks, with each function block designed to perform a specific function, such as, for example, a microprocessor function, a graphics processing unit (GPU) function, a communications function (e.g., WiFi, Bluetooth, and other communications), and the like.

As these circuits become more complex and densely packed, they inherently generate a significant amount of heat during operation. This heat generation poses serious challenges that can impact the performance, reliability, and lifespan of the ICs. For ICs comprising single substrates, the heat generated is primarily a result of the active transistors within the circuit. As the number of transistors on a single substrate increases, however, so does the heat generated. Stacked substrates present an even more complex thermal dissipation challenge. Stacking multiple substrates increases the density of the components, leading to even higher heat generation. The proximity of the substrates in a stacked configuration can hinder effective heat dissipation, causing heat to accumulate within as well as between the layers.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an electronic device includes one or more substrates carrying active circuitry; a heat sink structure disposed exterior to the one or more substrates; one or more thermal through-substrate vias (TTSVs) forming a first set of one or more thermally conductive paths between the one or more substrates and the heat sink structure; and one or more metallization lines disposed in the one or more substrates, wherein in a first mode of operation of the active circuitry, the one or more metallization lines carry active signals of the active circuitry, and in a second mode of operation of the active circuitry in which the one or more metallization lines do not carry active signals of the active circuitry, the one or more metallization lines are connected as heat-conductive branches forming a second set of one or more thermally conductive paths in thermal contact with the first set of one or more thermally conductive paths.

In an aspect, a thermal dissipation structure includes a heat sink structure disposed exterior to one or more substrates carrying active circuitry; one or more thermal through-substrate vias (TTSVs) forming a first set of one or more thermally conductive paths between the one or more substrates and the heat sink structure; and one or more metallization lines disposed in the one or more substrates, wherein in a first mode of operation of the active circuitry, the one or more metallization lines carry active signals of the active circuitry, and in a second mode of operation of the active circuitry, the one or more metallization lines do not carry active signals of the active circuitry and the one or more metallization lines are connected as heat-conductive branches forming a second set of one or more thermally conductive paths in thermal contact with the first set of one or more thermally conductive paths.

In an aspect, a method of operating a thermal dissipation structure to dissipate heat generated by active circuitry of one or more substrates includes providing one or more thermal through-substrate vias (TTSVs) through at least one substrate of the one or more substrates to form a first set of one or more thermally conductive paths between the at least one substrate of the one or more substrates and a heat sink structure; in a first mode of operation of the active circuitry, configuring one or more metallization lines of the at least one substrate to carry active signals of the active circuitry; and in a second mode of operation of the active circuitry in which the one or more metallization lines do not carry active signals of the active circuitry, connecting the one or more metallization lines as heat-conductive branches to the one or more TTSVs as thermally conductive lines and disconnecting the one or more metallization lines from operating as signal carrying lines.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1 shows an example of a thermal management architecture that may be used in the context of an electronic package having a single die mounted on a substrate, according to aspects of the disclosure.

FIG. 2 shows an example of a thermal management architecture that may be used in the context of an electronic package having a single die mounted on a substrate, according to aspects of the disclosure.

FIG. 3 shows an example of a three-dimensional electronic package, according to aspects of the disclosure.

FIG. 4 shows an example of a stacked substrate electronic package having through-substrate vias (TSVs), according to aspects of the disclosure.

FIG. 5 shows an example of thermal through-substrate vias (TTSVs) and heat-conductive branches of an example thermal dissipation structure, according to aspects of the disclosure.

FIG. 6A shows an electronic package having an example thermal dissipation structure in a state in which the active circuitry of the substrates of the electronic package are in the first mode of operation, according to aspects of the disclosure.

FIG. 6B shows the example thermal dissipation structure in a state in which the active circuitry of the substrates of the electronic package are in the second mode of operation, according to aspects of the disclosure.

FIG. 7A and FIG. 7B show an example in which an anti-fuse may be used to connect a metallization line as part of the thermal dissipation structure, according to aspects of the disclosure.

FIG. 8A and FIG. 8B show another example in which a plurality of anti-fuses may be used to connect a plurality of metallization lines as heat-conductive branches of the thermal dissipation structure, according to aspects of the disclosure.

FIG. 9 shows an example of a nanoelectromechanical system (NEMS) switch that may be used to selectively connect and disconnect metallization lines as heat-conductive branches of a thermal dissipation structure, according to aspects of the disclosure.

FIG. 10 illustrates an example of how a NEMS switch may be embedded in an electronic package, according to aspects of the disclosure.

FIG. 11 is a flowchart showing an example method of operating a thermal dissipation structure to dissipate heat generated by active circuitry of one or more substrates, according to aspects of the disclosure.

FIG. 12 illustrates a profile view of a package that includes a surface mount substrate, an integrated device, and an integrated passive device, according to aspects of the disclosure.

FIG. 13 illustrates an example method for providing or fabricating a package that includes an integrated device comprising an electronic component mounted in a core, according to aspects of the disclosure.

FIG. 14 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (PoP), System in Package (SiP), or System on Chip (SoC).

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

Advanced semiconductor fabrication nodes, notably those reaching 4 nm and 3 nm specifications, facilitate the integration of over 100 million transistors per square millimeter on silicon substrates. This technological advancement allows for a substantial number of functional logic components to be accommodated within a minimized silicon footprint, enhancing spatial efficiency and performance capabilities in microelectronic devices.

However, the escalation in logic density introduces significant engineering challenges, especially concerning power density and thermal management. Thermal constraints have become the predominant bottleneck in modern semiconductor design, surpassing other design parameters. High power density leads to increased heat generation, necessitating innovative thermal mitigation strategies to maintain device integrity and performance. In the absence of effective heat dissipation mechanisms, semiconductor devices are prone to performance throttling, reliability issues, and reduced operational lifespan.

These challenges are further compounded by the implementation of advanced packaging techniques, such as the 3D stacking observed in some modern processors. While these methods optimize die space and enable vertical IC integration, they also intensify thermal challenges due to the restricted heat dissipation, as demonstrated by the thermal thresholds in 3D cache-equipped variants (with limits ranging from 89° C. to 95° C.). This configuration results in heat accumulation within the stacked layers, demanding more sophisticated and efficient cooling solutions.

There is a need for enhanced thermal dissipation designs to support the continued trend toward vertical IC expansion and to improve the performance of two-dimensional (2D) designs by providing additional thermal headroom. The key to optimizing thermal dissipation lies in effectively managing heat sources within system-on-chips (SOCs). Greater dissipation efficiency can be achieved when heat generation is uniformly distributed across the die, preventing the formation of concentrated hot spots. This uniform thermal profile promotes more efficient heat transfer processes, making it easier to extract heat from SOCs and thereby improving overall system performance and reliability.

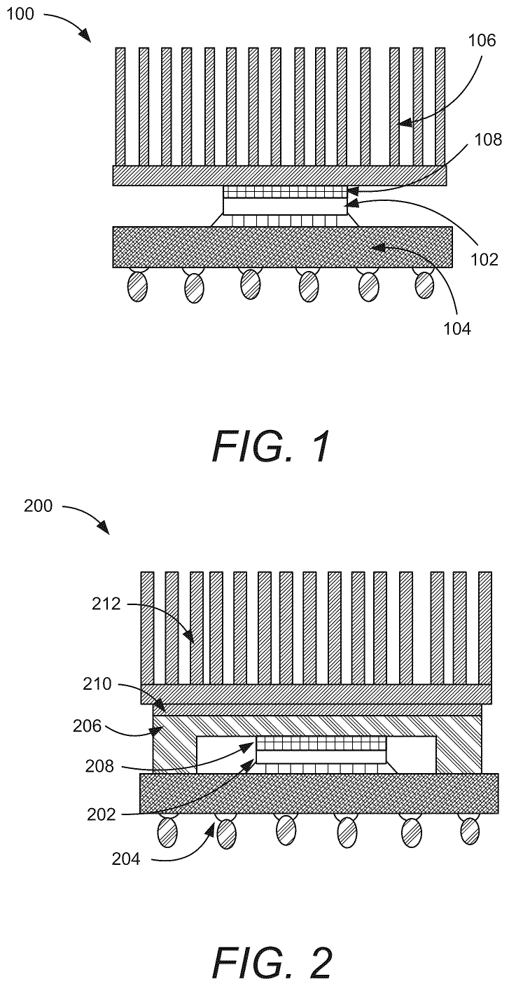

In the realm of flip-chip designs, there are two predominant architectures employed to facilitate heat dissipation from the silicon die, each leveraging thermal interface materials (TIMs) to enhance thermal conductivity and manage heat flow. FIG. 1 shows an example of a thermal management architecture that may be used in the context of an electronic package 100 having a single die 102 mounted on a substrate 104, according to aspects of the disclosure. In an aspect, the die 102 is directly coupled with a heatsink 106, utilizing a layer of thermal interface material (TIM) 108. The TIM 108 acts as a thermally conductive medium, filling the microscopic air gaps between the die 102 and heatsink 106 to reduce thermal resistance. The efficiency of heat transfer in the example shown in FIG. 1 is reliant on the properties of the selected TIM 108. In an aspect, the TIM 108 formed from a material with high thermal conductivity to effectively draw heat away from the die 102 4 dissipation by the heatsink 106.

FIG. 2 shows an example of a thermal management architecture that may be used in the context of an electronic package 200 having a single die 202 mounted on a substrate 204, according to aspects of the disclosure. Contrasting the direct connection approach shown in the thermal management architecture in FIG. 1, the thermal management architecture shown in FIG. 2 introduces an integrated heat spreader (IHS) 206 as an intermediary thermal conductor. The die 202 first interfaces with the IHS 206 via a TIM layer 208, effectively spreading the heat generated by the active circuits of the die 202 over a larger surface area to homogenize the thermal profile. In an aspect, a second TIM layer 210 is applied between the IHS 206 and a heatsink 212, further facilitating heat transfer. This dual-stage dissipation process tends to be more effective in managing hot spots and distributing heat uniformly, albeit with a slight increase in thermal resistance due to the additional layer.

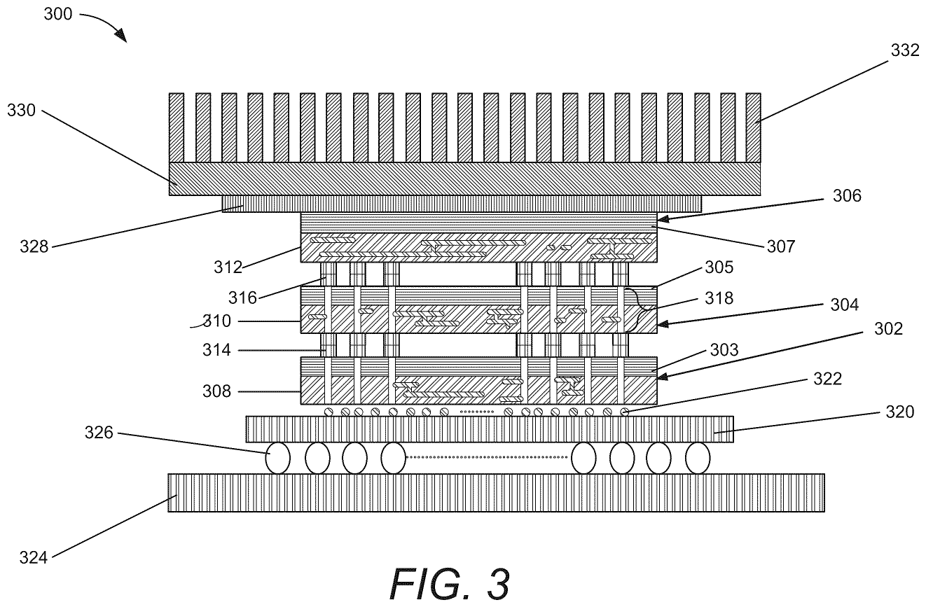

In the domain of three-dimensional (3D) ICs, managing heat dissipation poses another set of engineering challenges due to the structural intricacies of the multi-layered chip architectures. FIG. 3 shows an example of a three-dimensional electronic package 300, according to aspects of the disclosure. In this example, the electronic package 300 is a multi-substrate configuration comprised of three vertically stacked substrates, each comprising a die and a corresponding interconnect layer. Here, substrate 302 is the bottom-most substrate, substrate 304 is the middle substrate, and substrate 306 is the top substrate. Each substrate 302, 304, and 306 includes a die 303, 305, and 307 carrying active circuitry and a corresponding interconnect layer 308, 310, and 312. The interconnect layers 308, 310, and 312 play a role in routing signals and providing power to the circuitry on the dies 303, 305, and 307.

In this example, the substrates 302, 304, and 306 are interconnected using micro-connect structures 314 and 316 that establish a mechanical and electrical connection between the upper surface of one substrate and the interconnect layer of the substrate above it. These structures are employed to maintain the vertical communication and power flow between the substrates 302, 304, and 306.

Embedded within each substrate 302, 304, 306 and its corresponding interconnect layer 308, 310, 312 are Through Substrate Vias (TSVs) (see, e.g., TSV 318), which are vertical metallized pathways that carry power and signals to the active circuits on the dies 303, 305, 307, facilitating efficient layer-to-layer communication and power distribution within the stacked substrates.

The interconnect layer 308 of the lowermost substrate 302 is interfaced with a package substrate 320 through the use of C4 (Controlled Collapse Chip Connection) solder bumps 322. The C4 solder bumps 322 provide both mechanical support and electrical connectivity, ensuring signal and power continuity from the lowermost substrate 302 to the package substrate 320. Further, the package substrate 320 is mounted on a Printed Circuit Board (PCB) 324 using CV GAA (Compliant Vertical Grid Array Assembly) joints 326. These specialized CV GAA joints 326 provide reliable, high-density interconnections, accommodating the thermal and mechanical stresses between the package substrate and the PCB, thus ensuring the integrity of signal and power transmission to the broader electronic system.

The electronic package 300 also includes structures for managing heat dissipation. In this example, a TIM layer 328 is applied at the upper surface of substrate 306 to establish a thermally conductive link between the substrate 306 and a heat spreader 330. The heat spreader 330 is directly connected to a heat sink 332.

In an aspect, the signal-carrying TSVs may assist in transferring heat from the lower layers to the substrate 306. However, the heat sink 332 is situated only at the top layer (e.g., substrate 306) of the stack and is isolated from the lower layers (e.g., substrates 302, 304). Certain aspects of the disclosure are implemented with a recognition that this arrangement severely restricts the direct path of thermal conduction from the lower-level substrates 302, 304 to the heat sink 332, resulting in sub-optimal heat dissipation. Consequently, the lower substrates 302, 304 retain a higher thermal load, which directly impacts and restricts their operating frequency. The inability to efficiently extract the accumulated heat from the lower substrates 302, 304 means the IC cannot be operated at its maximum potential without risking thermal failure.

Certain aspects of the disclosure are directed to an electronic package having a thermal dissipation structure that establishes a more direct, conductive pathway from the lower-layer substrates to a heat sink structure (e.g., heat spreader, TIM layers, heat sinks, or combinations thereof) that are responsible for dispersing heat from the electronic package to the environment (e.g., ambient environment, cooling fluid environment, etc.). However, certain aspects of the disclosure are implemented with a recognition that potential solutions, such as the incorporation of multiple metallization layers within each die that are specifically dedicated to thermal conduction, present their own set of challenges. While theoretically effective, implementing such multiple dedicated layers can be prohibitively expensive, increase the complexity of the manufacturing process, are expensive to implement, slows fabrication, and adds unnecessary thickness to the IC.

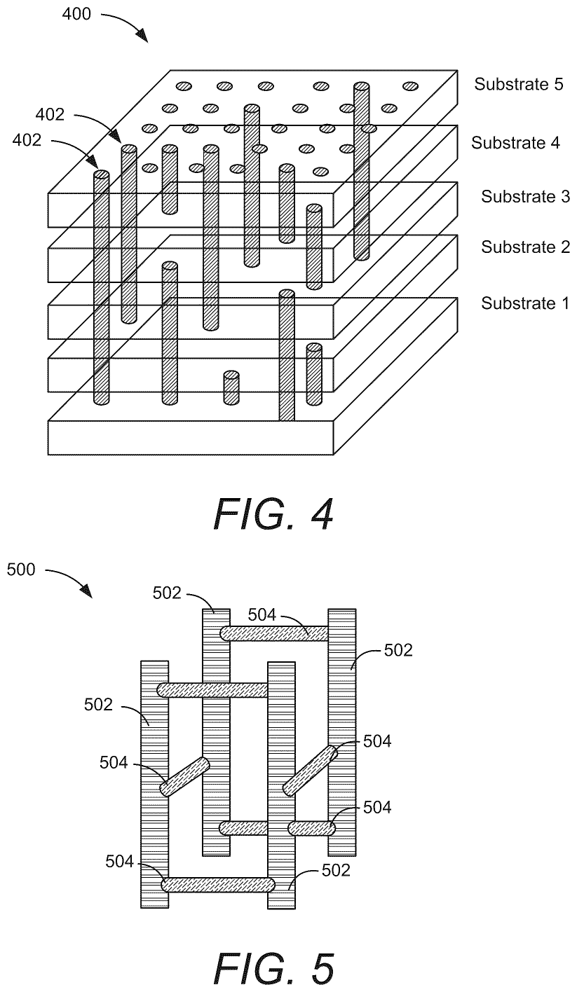

In IC fabrication technology, a through-substrate via (TSV) is a vertical electrical connection (via) that passes completely through a substrate, providing high-performance data traversal and better packaging density. FIG. 4 shows an example of a stacked substrate electronic package 400 having TSVs 402, according to aspects of the disclosure. In this example, the TSVs 402 (not all TSVs are labeled in FIG. 4 so as not to clutter the figure) form a network of vias that interconnect the multiple substrates (shown as Substrate 1 through Substrate 5) of the electronic package 400. In an aspect, each substrate may include one or more dies disposed on a corresponding interconnect layer. The TSVs 402 shown in FIG. 4 carry active signals (e.g., power signals, logic signals, etc.) associated with the active circuits formed on the dies of the substrates.

According to aspects of the disclosure, a thermal dissipation structure is incorporated into the basic structure of the electronic package 400, shown in FIG. 4. The thermal dissipation structure includes structures forming thermally conductive paths within and between the substrates that facilitate extraction of heat from the electronic package 400.

According to aspects of the disclosure, a thermally conductive path in the context of a thermal dissipation structure within an electronic package refers to a specifically designed route or medium within the electronic package that facilitates efficient heat transfer away from the heat-generating components (e.g., active circuits of the dies). In an aspect, a thermally conductive path may be characterized by materials or structures with high thermal conductivity, allowing for rapid and efficient heat transfer. These could include, but are not limited to, metal layers, thermal vias, specialized gels or pastes, and composite materials designed to draw heat away from critical areas of the electronic package.

In accordance with certain aspects of the disclosure, an example thermal dissipation structure may include various types of heat-conducting elements that are interconnected to serve as thermally conductive paths that collect heat from the dies and conduct the heat to a heat sink structure for dissipation from the electronic package 400. In an aspect, the thermal dissipation structure may include dedicated Thermal TSVs (TTSVs) extending between the different tiers of the electronic package to facilitate heat transfer between the lower tiers to an uppermost tier having a heat sink structure may be used to dissipate heat from the electronic package. The TTSVs of the thermal dissipation structure, unlike the TSVs 402 shown in FIG. 4, are dedicated to collecting heat and form thermally conductive paths between the tiers of the electronic package 400.

In accordance with certain aspects of the disclosure, the thermal dissipation structure includes heat-conductive branches that form thermally conductive paths used to conduct heat from the substrates to the TTSVs. FIG. 5 shows an example of TTSVs and heat-conductive branches of an example thermal dissipation structure 500, according to aspects of the disclosure. In an aspect, the thermal dissipation structure 500 may include a plurality of TTSVs 502 extending through all of the substrates. In certain scenarios, a given TTSV 502 need not extend through all of the substrates provided that the given TTSV has a thermally conductive path connecting it to other TTSVs that ultimately conduct heat to the thermal dissipation module.

The example thermal dissipation structure 500 also includes permanent heat-conductive branches 504 that are disposed between the tiers. In an aspect, the permanent heat-conductive branches 504 are fixed during the fabrication stage and dedicated to heat transfer. In the example shown in FIG. 5, the permanent heat-conductive branches 504 of the thermal dissipation structure 500 extend between the TTSVs 502 and provide thermally conductive paths to the TTSVs 502. However, it will be understood, based on the teachings of this disclosure, that certain permanent heat-conductive branches 504 may be in contact with a single TTSV 502 and, as will be discussed in further detail below, still be used as part of the thermal dissipation structure 500.

Certain aspects of the disclosure are implemented with a recognition that metallization lines associated with the dies of an electronic package may carry active signals of the active circuits of the dies at one time while being inhibited from carrying at another. For purposes of the disclosure, the state of the metallization lines may be described in the context of the state (e.g., mode of operation) of the active circuits that the metallization lines serve. According to aspects of the disclosure, the metallization lines carry active signals of the active circuitry in a first mode of operation of the active circuitry in which the active circuitry associated with the active circuitry is operating for a given purpose. In an aspect, the metallization lines do not carry active signals of the active circuitry with which they are associated in a second mode of operation of the active circuitry since the active circuitry no longer needs access to the metallization lines for the given purpose. Certain aspects of the disclosure recognize that the metallization lines that no longer carry active signals may be used as heat-conductive branches during the second mode of operation of the active circuitry. Such metallization lines may be used as part of the thermal dissipation structure to provide a set of thermally conductive paths to the TTSVs (e.g., through direct attachment to the TTSVs or through the permanent heat-conductive branches).

In an aspect, the first mode of operation may be associated with a diagnostic mode (e.g., debugging and/or quality control mode) in which the components of the electronic package are tested. In such instances, certain metallization lines only carry active signals when the electronic package is subject to diagnostic testing. Once such diagnostic operations are completed, the metallization lines are no longer needed to carry active signals of the active circuitry. At this point, the active circuitry is effectively in the second mode of operation where the metallization lines no longer carry the active signals but in which the active circuitry functions for its intended end-use (e.g., the active circuitry operates in a normal mode). Such unused metallization lines (e.g., the metallization lines used to carry diagnostic control signals in the first mode are no longer needed for carrying active signals for standard operation of the corresponding active control circuits) may be connected as heat-conductive branches of the thermal dissipation structure.

In view of the foregoing, certain aspects of the disclosure are directed to a thermal dissipation structure that is configured to dissipate heat generated by the active circuitry of one or more dies. In an aspect, the thermal dissipation structure includes a heat sink structure. The thermal dissipation structure further includes one or more thermal through-substrate vias (TTSVs) forming a first set of one or more thermally conductive paths between at least one die of one or more dies carrying active circuitry and the heat sink structure. In an aspect, the thermal dissipation structure further includes one or more metallization lines disposed in the at least one die, wherein 1) in a first mode of operation of the active circuitry, the one or more metallization lines carry active signals of the active circuitry, and 2) in a second mode of operation of the active circuitry in which the one or more metallization lines do not carry active signals of the active circuitry, the one or more metallization lines are connected as heat-conductive branches forming a second set of one or more thermally conductive paths in thermal contact with the first set of one or more thermally conductive paths.

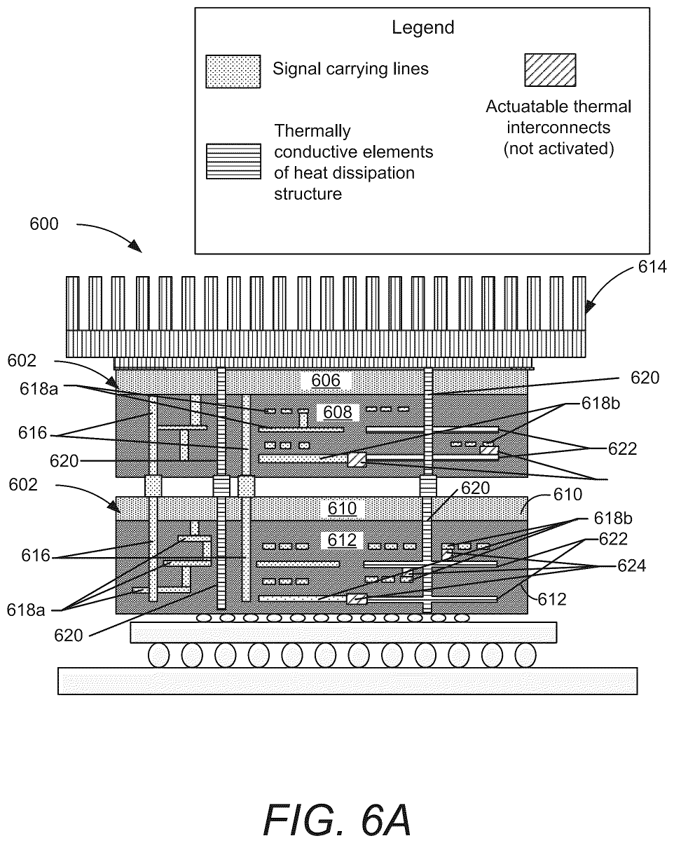

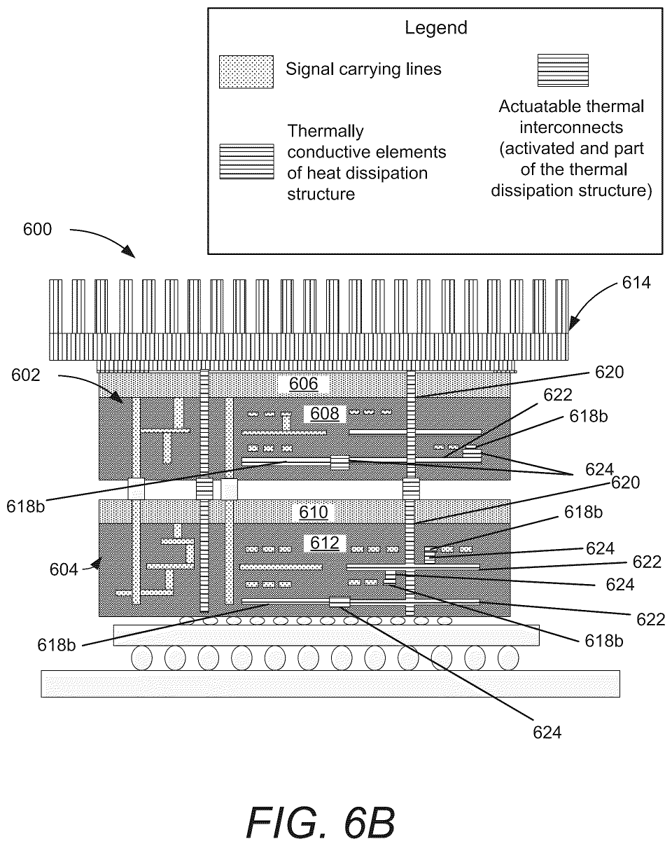

FIG. 6A shows an electronic package 600 having an example thermal dissipation structure in a state in which the active circuitry of the substrates of the electronic package are in the first mode of operation, according to aspects of the disclosure. In this example, the electronic package 600 includes two substrates 602 and 604. The substrate 602 includes a die 606 carrying active circuitry (not shown) and an interconnect structure 608. Similarly, substrate 604 includes a die 610 carrying active circuitry (not shown) and an interconnect structure 612. A heat sink structure 614 is disposed at an upper portion of the electronic package 600 and configured to disburse heat generated in the electronic package 600 from the electronic package 600 to, for example, the ambient environment or other heat disbursement medium. In an aspect, the heat sink structure 614 may include a heat spreader, a heat sink, or a combination thereof.

In this example, the electronic package 600 includes signal-carrying metallization lines, thermally conductive elements, and actuatable thermal interconnects as indicated in the Legend. Here, the signal carrying metallization lines include a plurality of TSVs 616 and metallization lines 618a and 618b (not all metallization lines are labeled) that carry electronic signals associated with the active circuits of the substrates 602 and 604. The thermally conductive elements include one or more TTSVs 620 and corresponding heat-conductive branches 622. The TTSVs 620 and heat-conductive branches 622 form a thermally conductive path between the substrates 602 and 604 and the heat sink structure 614.

The actuatable thermal interconnects 624 are configured between the metallization lines 618b and the heat-conductive branches 622. However, the actuatable thermal interconnects 624 are not active in FIG. 6A since the active circuitry of the substrates is in a first operating mode in which the metallization lines 618b carry signals associated with the active circuitry.

FIG. 6B shows the example thermal dissipation structure in a state in which the active circuitry of the substrates of the electronic package are in the second mode of operation, according to aspects of the disclosure. In this second mode of operation, the metallization lines 618b no longer carry signals of the active circuitry and, as such, may be incorporated into the thermal dissipation structure. To this end, the actuatable thermal interconnects 624 have been activated thereby providing thermally conductive paths between the metallization lines 618b and TTSVs 620 via the heat-conductive branches 622.

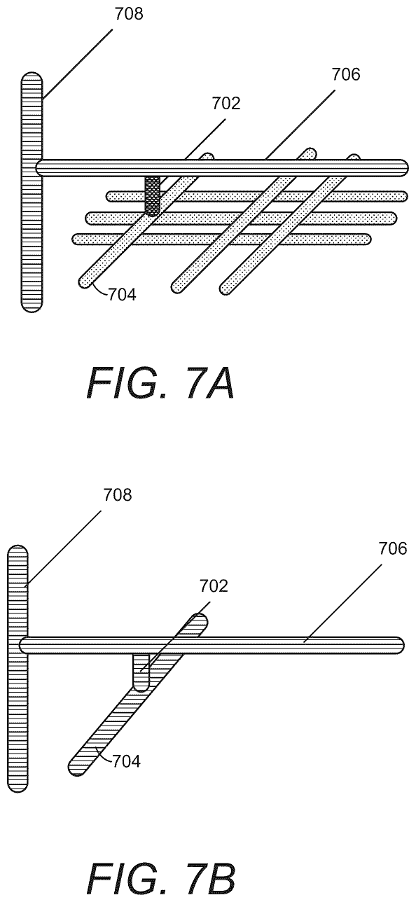

In scenarios in which the metallization lines 618b have been dedicated to diagnostic functions, the actuatable thermal interconnects 624 may be permanently activated to include the metallization lines 618b as part of the thermal dissipation structure upon completion of the diagnostic operations. To this end, fuses and/or anti-fuses may be interposed between the metallization lines and other structures of the thermal dissipation structure (e.g., permanent heat-conductive branches). FIG. 7A and FIG. 7B show an example in which an anti-fuse 702 may be used to connect a metallization line 704 as part of the thermal dissipation structure, according to aspects of the disclosure. In FIG. 7A, the active circuitry associated with the metallization line 704 is operating in the first mode and, as such, carries active signals associated with the corresponding active circuitry. Consequently, the anti-fuse 702 is non-conductive and does not provide a thermally conductive path to the other portions of the thermal dissipation structure (shown here as permanent heat conducting branch 706 and TTSVs 708). Once diagnostic operations have been completed, metallization line 704 is no longer needed by the associated active circuitry and may be connected as part of the thermal dissipation structure. To this end, anti-fuse 702 is actuated so that the metallization line 704 is placed in thermal contact with other portions of the thermal dissipation structure (e.g., permanent heat-conducting branch 706). The actuated anti-fuses 702 thereby provides a thermally conductive path to the thermal dissipation structure. As such, the metallization line 704 is now part of the thermal dissipation structure as shown in FIG. 7B. In certain scenarios, the metallization line 704 may be connected to carry active signals of the associated active circuitry through a fuse (not shown) during the first mode. The fuse may be actuated to electrically disconnect the metallization line 704 from the associated active circuitry in the second mode.

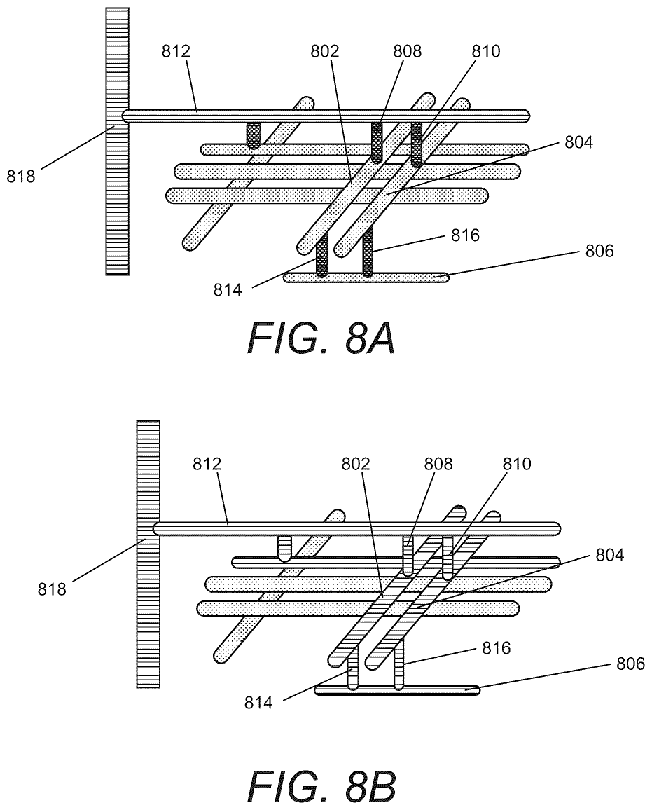

FIG. 8A and FIG. 8B show another example in which a plurality of anti-fuses may be used to connect a plurality of metallization lines as heat-conductive branches of the thermal dissipation structure, according to aspects of the disclosure. In this example, metallization lines 802, 804, 806 may be associated with redundant versions of active circuitry employed in the electronic package. Here, anti-fuses 808 and 810 are respectively disposed between metallization lines 802 and 804 and permanent heat conducting branch 812. Additionally, anti-fuses 814 and 816 are respectively disposed between metallization line 806 and metallization lines 802, 804.

Once the diagnostic operations have been completed and/or a determination that such redundant versions of the active circuitry need not be utilized in further operations of the device embodied in the electronic package, the anti-fuses 808, 810, 814, and 816 may be actuated to engage the metallization lines 802, 804, 806 as heat-conductive branches of the thermal dissipation structure as shown in FIG. 8B. In this example, the actuated anti-fuses 814 and 816 provide thermally conductive paths between the metallization line 806 and metallization lines 802, 804. In turn, the actuated anti-fuses 808, 810 provide thermally conductive paths between the metallization lines 802, 804 and the permanent heat-conductive branch 812, which provides a thermally conductive path to the TTSV 818. It will be recognized, based on the teachings of the present disclosure, that standard TSVs may be similarly connected as heat-conductive branches of the thermal dissipation structure when the standard TSVs are no longer needed for carrying active signals.

Certain aspects of the disclosure recognize that certain portions of the active circuitry may be active at one time but go to a quiescent state at another time. Further, certain aspects of the disclosure recognize that certain metallization lines associated with the portions of the active circuitry that are in the quiescent state often do not carry active signals associated with those portions of the active circuitry when those portions of the active circuitry are in the quiescent state. As such, certain aspects of the disclosure are implemented with a recognition that the metallization lines that do not carry active signals when portions of the active circuitry are in the quiescent state (e.g. when the portions of the active circuitry are in the second mode) may be temporarily incorporated in the thermal dissipation structure as heat-conductive branches. Accordingly, certain aspects of the disclosure are directed to temporarily incorporating metallization lines associated with active circuitry into the thermal dissipation structure when at least a portion of the active circuitry is in a quiescent state. Once such portions of the active circuitry exit the quiescent state, the corresponding metallization lines may be disconnected as heat-conductive branches and used to carry active signals of the active circuitry.

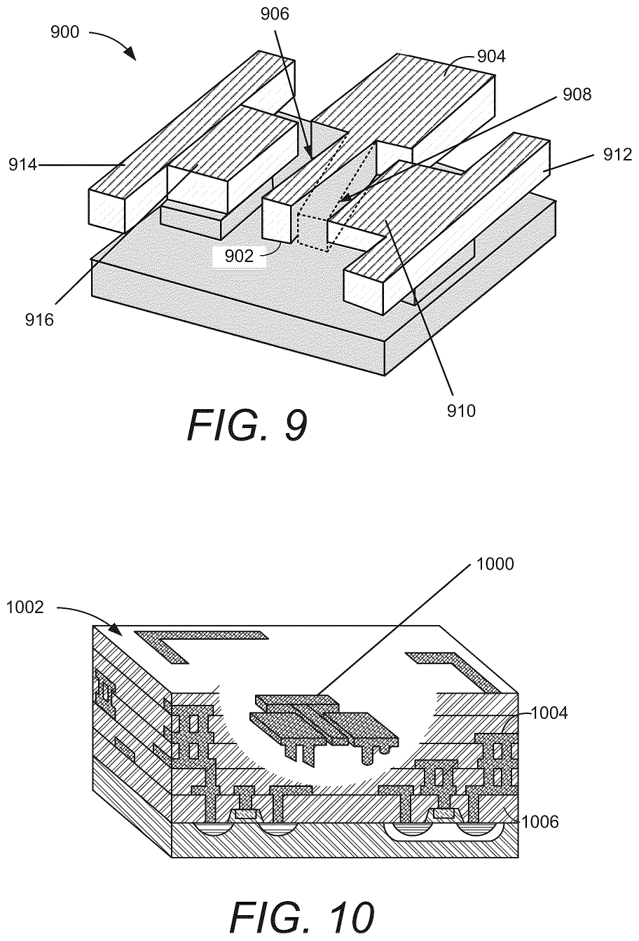

In certain aspects of the disclosure, the metallization lines functioning in the foregoing manner may be selectively interconnected with the thermal dissipation structure using nanoelectromechanical system (NEMS) switches. FIG. 9 shows an example of a nanoelectromechanical system (NEMS) switch 900 that may be used to selectively connect and disconnect metallization lines as heat-conductive branches of a thermal dissipation structure, according to aspects of the disclosure. The NEMS switch 900 shown in FIG. 9 is merely an example of a NEMS structure and is incorporated in the disclosure for illustrative purposes. Accordingly, it will be recognized, based on the teachings of the present disclosure, that other configurations of NEMS may be utilized.

In this example, NEMS switch 900 includes a movable beam 902 that is fixed at one end to an anchor pad 904. In an aspect, the anchor pad 904 is connected to one or more heat-conductive branches of the thermal dissipation structure. The movable beam 902 is movable between a static position (e.g., a first switch state shown at 906) in which the movable beam 902 is free-standing, and an active position (e.g., second switch state shown at 908) in which the movable beam 902 is in contact with a terminal element 910. In an aspect, the terminal element 910 is in thermal contact with a metallization line 912 that is to be selectively connected and removed as a heat-conducting branch of the thermal dissipation structure.

The NEMS switch 900 may be actuated at terminal 916 to move the movable beam 902 between the static position 906 and the active position 908 in response to a control signal provided at terminal 916. Here, the terminal 916 receives a control signal carried by line 914. The control signal carried by line 914 provides an indication of whether the active circuitry associated with metallization line 912 is in a quiescent state. When the active circuitry associated with the metallization line 912 is in the quiescent state, the movable beam 902 is driven to the active position 908 so that the movable beam 902 and anchor pad 904 provide a thermally conductive path to one or more elements of the thermal dissipation structure. When the active circuitry associated with the metallization line 912 exits the quiescent state, this change in state is indicated by the signal at line 914, which allows the movable beam 902 to return to the static position 906. In the static position 906, metallization line 912 is disconnected from the thermal dissipation structure and does not operate as a heat-conductive branch, at which time the metallization line is free to carry active signals of the associated active circuitry.

In accordance with certain aspects of the disclosure, signals such as Reset and Power Gate signals associated with the active circuitry may be provided on line 914 to activate and deactivate the NEMS switch 900 since such signals are often indicative of whether the active circuitry is in an active state or quiescent state. Additionally, or in the alternative, the control signal on line 914 may be provided by a thermal control system that is configured to control the operation of the NEMS switch 900 through activation and deactivation of the NEMS of the thermal dissipation structure.

Although metallization line 912 has been described as being associated with active circuitry, the NEMS switch 900 may be used to selectively provide thermally conductive paths between different portions of the thermal dissipation structure. In an example, standard TSVs can be connected by a thermally conductive path to the anchor pad 904 and act as TTSVs during times in which the standard TSVs are not used to carry active signals.

FIG. 10 illustrates an example of how a NEMS switch may be embedded in an electronic package, according to aspects of the disclosure. Here, the NEMS switch 1000 is embedded in a substrate 1002 having multiple metallization layers 1004 and corresponding insulating layers 1006.

The materials for the permanent, one-time, and dynamic branches may be chosen such that the electrical conductance while carrying the electrical signal for processing and thermal conductance while absorbing heat as part of ETCN in the required directions are both within the respective performance constraints.

The thermal dissipation structure of the disclosure may be used to reduce the temperature of isolated hotspots in system-on-a-chip (SOC) devices and provides more flexibility in thermal design. In certain aspects, the heat-conductive branches of the thermal dissipation structure may be concentrated in such potential hotspots.

Additionally, the disclosed thermal dissipation structure may be used to mitigate the differential aging issues seen in SOCs. In an aspect, the differential aging may be due to the circuitry associated with the hot spot aging quicker than the other circuitry. As the differential aging is user workload specific, it cannot typically be compensated at the design phase. With heat being absorbed by surrounding logic and metal wire, the aging becomes reasonably similar across the different circuitry. This may also reduce the power consumption due to lower operating temperature and lower voltage requirements as all components are aging slowly and nearly uniformly, which in turn may result in a better lifespan of the SOC. In certain scenarios, the estimated TTSV area overhead is less than 0.3% to 0.5% and provides more thermal stability with the addition of more TTSVs.

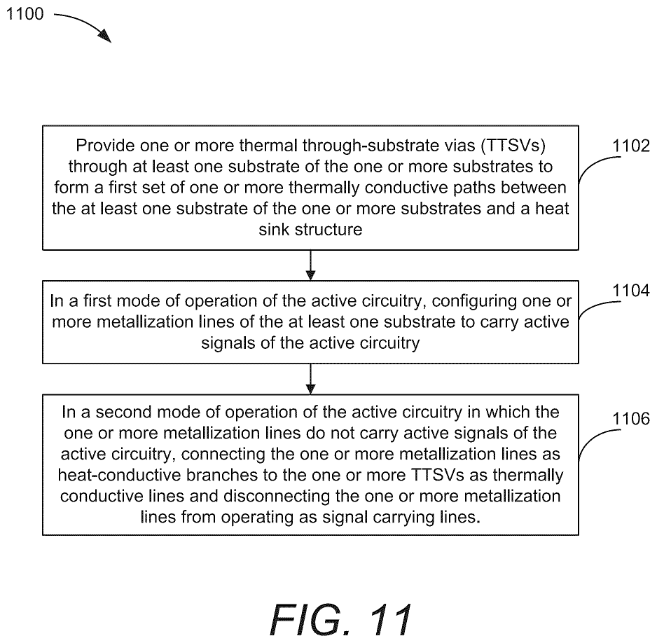

FIG. 11 is a flowchart showing an example method 1100 of operating a thermal dissipation structure to dissipate heat generated by active circuitry of one or more substrates, according to aspects of the disclosure. At operation 1102, one or more thermal through-substrate vias (TTSVs) are provided through at least one substrate of the one or more substrates to form a first set of one or more thermally conductive paths between the at least one substrate of the one or more substrates and a heat sink structure. At operation 1104, in a first mode of operation of the active circuitry, one or more metallization lines of the at least one substrate are configured to carry active signals of the active circuitry. At operation 1106, in a second mode of operation of the active circuitry in which the one or more metallization lines do not carry active signals of the active circuitry, the one or more metallization lines are connected as heat-conductive branches to the one or more TTSVs as thermally conductive lines and the one or more metallization lines are disconnected from operating as signal carrying lines.

A technical advantage of the method 1100 is that it provides a robust thermal dissipation structure that utilizes existing structures of the electronic package to implement the thermal dissipation structure thereby limiting the number of structures that need to be added to the electronic package to implement the thermal dissipation structure.

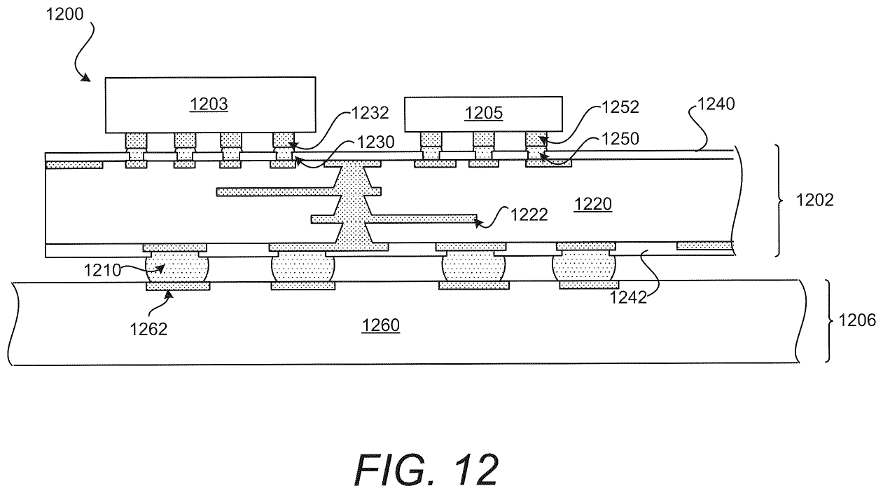

FIG. 12 illustrates a profile view of a package 1200 that includes a surface mount substrate 1202, an integrated device 1203, and an integrated passive device 1205, according to aspects of the disclosure. The package 1200 may be coupled to a printed circuit board (PCB) 1206 through a plurality of solder interconnects 1210. The PCB 1206 may include at least one board dielectric layer 1260 and a plurality of board interconnects 1262.

The surface mount substrate 1202 includes at least one dielectric layer 1220 (e.g., substrate dielectric layer), a plurality of interconnects 1222 (e.g., substrate interconnects), a solder resist layer 1240 and a solder resist layer 1242. The integrated device 1203 may be coupled to the surface mount substrate 1202 through a plurality of solder interconnects 1230. The integrated device 1203 may be coupled to the surface mount substrate 1202 through a plurality of pillar interconnects 1232 and the plurality of solder interconnects 1230. The integrated passive device 1205 may be coupled to the surface mount substrate 1202 through a plurality of solder interconnects 1250. The integrated passive device 1205 may be coupled to the surface mount substrate 1202 through a plurality of pillar interconnects 1252 and the plurality of solder interconnects 1250.

The package (e.g., 1200) may be implemented in a radio frequency (RF) package. The RF package may be a radio frequency front end (RFFE) package. A package (e.g., 1200) may be configured to provide Wireless Fidelity (WiFi) communication and/or cellular communication (e.g., 2G, 3G, 4G, 5G). The package (e.g., 1200) may be configured to support Global System for Mobile (GSM) Communications, Universal Mobile Telecommunications System (UMTS), and/or Long-Term Evolution (LTE). The package (e.g., 1200) may be configured to transmit and receive signals having different frequencies and/or communication protocols.

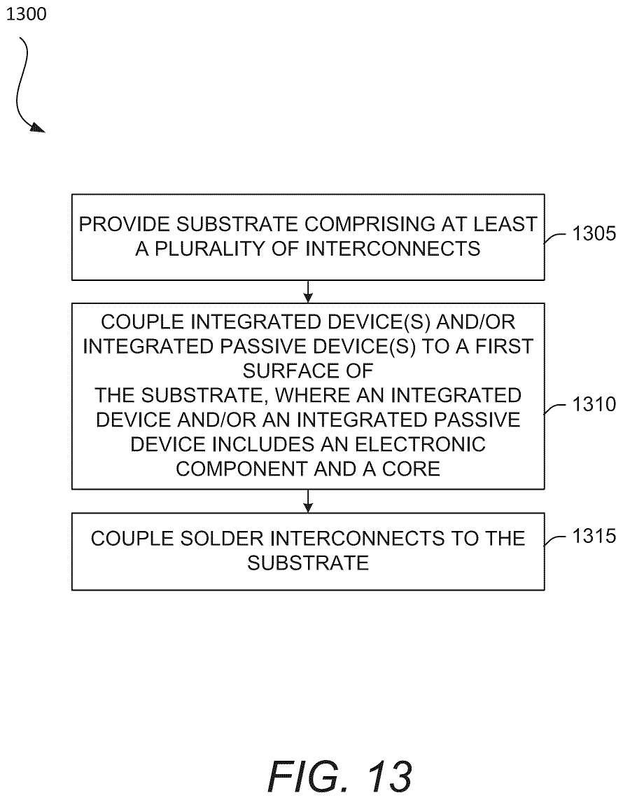

FIG. 13 illustrates an example method 1300 for providing or fabricating a package that includes an integrated device comprising an electronic component mounted in a core, according to aspects of the disclosure. In some implementations, the method 1300 of FIG. 13 may be used to provide or fabricate the package 1200 of FIG. 12 described in the disclosure. However, the method 1300 may be used to provide or fabricate any of the packages described in the disclosure.

It should be noted that the method of FIG. 13 may combine one or more processes in order to simplify and/or clarify the method for providing or fabricating a package that includes an integrated device comprising an electronic component mounted in a core, according to aspects of the disclosure. In some implementations, the order of the processes may be changed or modified.

The method provides (at 1305) a substrate (e.g., 1202). The substrate 1202 may be provided by a supplier or fabricated. The substrate 1202 includes at least one dielectric layer 1220 and a plurality of interconnects 1222. The substrate 1202 may include an embedded trace substrate (ETS). In some implementations, the at least one dielectric layer 1220 may include prepreg layers.

The method couples (at 1310) at least one integrated device (e.g., 1203) to the first surface of the substrate (e.g., 1202). For example, the integrated device 1203 may be coupled to the substrate 1202 through the plurality of pillar interconnects 1232 and the plurality of solder interconnects 1230. The plurality of pillar interconnects 1232 may be optional. The plurality of solder interconnects 1230 are coupled to the plurality of interconnects 1222. A solder reflow process may be used to couple the integrated device 1203 to the plurality of interconnects through the plurality of solder interconnects 1230.

The method also couples (at 1310) at least one integrated passive device (e.g., 1205) to the first surface of the substrate (e.g., 1202). For example, the integrated passive device 805 may be coupled to the substrate 1202 through the plurality of pillar interconnects 1252 and the plurality of solder interconnects 1250. The plurality of pillar interconnects 1252 may be optional. The plurality of solder interconnects 1250 are coupled to the plurality of interconnects 1222. A solder reflow process may be used to couple the integrated passive device 1205 to the plurality of interconnects through the plurality of solder interconnects 1250.

The method couples (at 1315) a plurality of solder interconnects (e.g., 1210) to the second surface of the substrate (e.g., 1202). A solder reflow process may be used to couple the plurality of solder interconnects 1210 to the substrate.

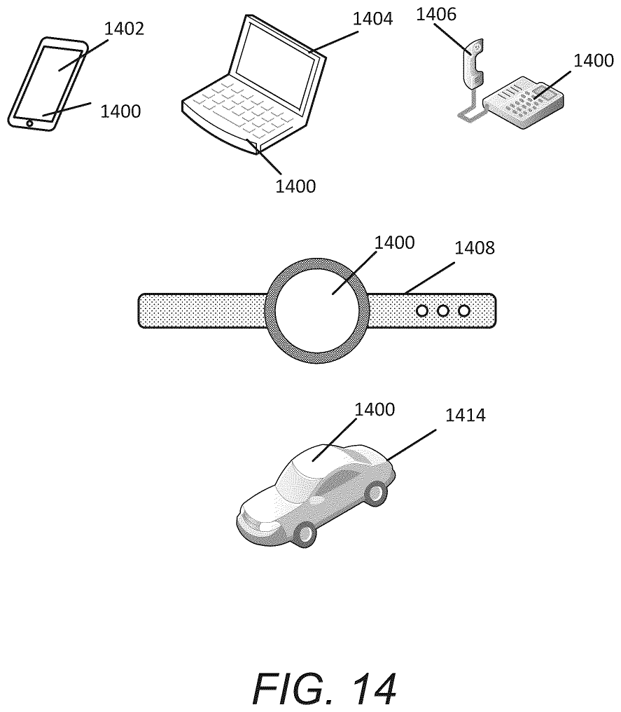

FIG. 14 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (PoP), System in Package (SiP), or System on Chip (SoC). For example, a mobile phone device 1402, a laptop computer device 1404, a fixed location terminal device 1406, a wearable device 1408, or automotive vehicle 1414 may include a device 1400 as described herein. The device 1400 may be, for example, any of the devices and/or integrated circuit (IC) packages described herein. The devices 1402, 1404, 1406 and 1408 and the vehicle 1410 illustrated in FIG. 14 are merely exemplary. Other electronic devices may also feature the device 1400 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

Implementation examples are described in the following numbered aspects:

Aspect 1. An electronic device, comprising: one or more substrates carrying active circuitry; a heat sink structure disposed exterior to the one or more substrates; one or more thermal through-substrate vias (TTSVs) forming a first set of one or more thermally conductive paths between the one or more substrates and the heat sink structure; and one or more metallization lines disposed in the one or more substrates, wherein in a first mode of operation of the active circuitry, the one or more metallization lines carry active signals of the active circuitry, and in a second mode of operation of the active circuitry in which the one or more metallization lines do not carry active signals of the active circuitry, the one or more metallization lines are connected as heat-conductive branches forming a second set of one or more thermally conductive paths in thermal contact with the first set of one or more thermally conductive paths.

Aspect 2. The electronic device of aspect 1, wherein: the one or more TTSVs comprise a plurality of TTSVs; and the second set of one or more thermally conductive paths are placed in thermal contact with the first set of one or more thermally conductive paths through one or more permanent heat-conductive branches extending between the plurality of TTSVs.

Aspect 3. The electronic device of any of aspects 1 to 2, further comprising: one or more anti-fuses configured to connect the one or more metallization lines as the heat-conductive branches; and one or more fuses configured to disconnect the one or more metallization lines from carrying the active signals of the active circuitry.

Aspect 4. The electronic device of any of aspects 1 to 3, further comprising: a set of one or more nanoelectromechanical system (NEMS) switches having a first switch state in which the first set of one or more NEMS switches is configured to connect the one or more metallization lines as the heat-conductive branches, and a second switch state in which the first set of one or more NEMS switches is configured to remove the one or more metallization lines as the heat-conductive branches.

Aspect 5. The electronic device of any of aspects 1 to 4, wherein: the first mode of operation of the active circuitry is a diagnostic mode of operation of the active circuitry; and the second mode of operation of the active circuitry is a normal mode of operation of the active circuitry.

Aspect 6. The electronic device of any of aspects 1 to 5, wherein: the first mode of operation of the active circuitry is a normal mode of operation of the active circuitry; and the second mode of operation of the active circuitry is associated one or more portions of the active circuitry being in a quiescent state.

Aspect 7. The electronic device of aspect 6, wherein: the one or more metallization lines carry active signals associated with the one or more portions of the active circuitry when the active circuitry is in the first mode of operation and do not carry active signals associated with the one or more portions of the active circuitry when the active circuitry is in the second mode of operation.

Aspect 8. The electronic device of any of aspects 1 to 7, wherein: the one or more substrates comprise a plurality of stacked substrates; the one or more TTSVs extend through the plurality of stacked substrates to form the first set of one or more thermally conductive paths; and the first set of one or more thermally conductive paths includes at least one thermally conductive path between each substrate of the plurality of stacked substrates and the heat sink structure.

Aspect 9. The electronic device of any of aspects 1 to 8, wherein the electronic device comprises at least one of: a music player; a video player; an entertainment unit; a navigation device; a communications device; a mobile device; a mobile phone; a smartphone; a personal digital assistant; a fixed location terminal; a tablet computer, a computer; a wearable device; a laptop computer; a server; an internet of things (IoT) device; or a device in an automotive vehicle.

Aspect 10. A thermal dissipation structure, comprising: a heat sink structure disposed exterior to one or more substrates carrying active circuitry; one or more thermal through-substrate vias (TTSVs) forming a first set of one or more thermally conductive paths between the one or more substrates and the heat sink structure; and one or more metallization lines disposed in the one or more substrates, wherein in a first mode of operation of the active circuitry, the one or more metallization lines carry active signals of the active circuitry, and in a second mode of operation of the active circuitry, the one or more metallization lines do not carry active signals of the active circuitry and the one or more metallization lines are connected as heat-conductive branches forming a second set of one or more thermally conductive paths in thermal contact with the first set of one or more thermally conductive paths.

Aspect 11. The thermal dissipation structure of aspect 10, wherein: the one or more TTSVs comprise a plurality of TTSVs; and the second set of one or more thermally conductive paths are placed in thermal contact with the first set of one or more thermally conductive paths through one or more permanent heat-conductive branches extending between the plurality of TTSVs.

Aspect 12. The thermal dissipation structure of any of aspects 10 to 11, further comprising: one or more anti-fuses configured to connect the one or more metallization lines as the heat-conductive branches; and one or more fuses configured to disconnect the one or more metallization lines from carrying the active signals of the active circuitry.

Aspect 13. The thermal dissipation structure of any of aspects 10 to 12, further comprising: a set of one or more nanoelectromechanical system (NEMS) switches having a first switch state in which the first set of one or more NEMS switches is configured to connect the one or more metallization lines as the heat-conductive branches, and a second switch state in which the first set of one or more NEMS switches is configured to disconnect the one or more metallization lines from functioning as the heat-conductive branches.

Aspect 14. The thermal dissipation structure of any of aspects 10 to 13, wherein: the first mode of operation of the active circuitry is a diagnostic mode of operation of the active circuitry; and the second mode of operation of the active circuitry is a normal mode of operation of the active circuitry.

Aspect 15. The thermal dissipation structure of any of aspects 10 to 14, wherein: the first mode of operation of the active circuitry is a normal mode of operation of the active circuitry; and the second mode of operation of the active circuitry is associated one or more portions of the active circuitry being in a quiescent state.

Aspect 16. The thermal dissipation structure of aspect 15, wherein: the one or more metallization lines carry active signals associated with the one or more portions of the active circuitry when the active circuitry is in the first mode of operation and do not carry active signals associated with the one or more portions of the active circuitry when the active circuitry is in the second mode of operation.

Aspect 17. The thermal dissipation structure of any of aspects 10 to 16, wherein: the one or more substrates comprise a plurality of stacked substrates; the one or more TTSVs extend through the plurality of stacked substrates to form the first set of one or more thermally conductive paths; and the first set of one or more thermally conductive paths includes at least one thermally conductive path between each substrate of the plurality of stacked substrates and the heat sink structure.

Aspect 18. The thermal dissipation structure of any of aspects 10 to 17, wherein the heat sink structure comprises: a heat spreader; a heat sink; or a combination thereof.

Aspect 19. A method of operating a thermal dissipation structure to dissipate heat generated by active circuitry of one or more substrates, the method comprising: providing one or more thermal through-substrate vias (TTSVs) through at least one substrate of the one or more substrates to form a first set of one or more thermally conductive paths between the at least one substrate of the one or more substrates and a heat sink structure; in a first mode of operation of the active circuitry, configuring one or more metallization lines of the at least one substrate to carry active signals of the active circuitry; and in a second mode of operation of the active circuitry in which the one or more metallization lines do not carry active signals of the active circuitry, connecting the one or more metallization lines as heat-conductive branches to the one or more TTSVs as thermally conductive lines and disconnecting the one or more metallization lines from operating as signal carrying lines.

Aspect 20. The method of aspect 19, further comprising: actuating one or more anti-fuses to connect the one or more metallization lines as the heat-conductive branches; and actuating one or more fuses to disconnect the one or more metallization lines from carrying the active signals of the active circuitry.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. The terms “top” and “bottom” are arbitrary. A component that is located on top may be located over a component that is located on the bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metallization layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the detailed description above, it can be seen that different features are grouped together in examples. This manner of disclosure should not be understood as an intention that the example aspects have more features than are explicitly mentioned in each aspect. Rather, the various aspects of the disclosure may include fewer than all features of an individual example aspect disclosed. Therefore, the following aspects should hereby be deemed to be incorporated in the description, wherein each aspect by itself can stand as a separate example. Although each dependent aspect can refer in the aspects to a specific combination with one of the other aspects, the aspect(s) of that dependent aspect are not limited to the specific combination. It will be appreciated that other example aspects can also include a combination of the dependent aspect(s) with the subject matter of any other dependent aspect or independent aspect or a combination of any feature with other dependent and independent aspects. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of an aspect can be included in any other independent aspect, even if the aspect is not directly dependent on the independent aspect.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An electronic device, comprising:
one or more substrates with active circuitry;
a heat sink structure disposed exterior to the one or more substrates;
one or more thermal through-substrate vias (TTSVs) forming a first set of one or more thermally conductive paths between the one or more substrates and the heat sink structure; and
one or more metallization lines disposed in the one or more substrates, wherein
in a first mode of operation of the active circuitry, the one or more metallization lines carry active signals of the active circuitry, and
in a second mode of operation of the active circuitry in which the one or more metallization lines do not carry active signals of the active circuitry, the one or more metallization lines are connected as heat-conductive branches forming a second set of one or more thermally conductive paths in thermal contact with the first set of one or more thermally conductive paths.

2. The electronic device of claim 1, wherein:
the one or more TTSVs comprise a plurality of TTSVs; and
the second set of one or more thermally conductive paths are placed in thermal contact with the first set of one or more thermally conductive paths through one or more permanent heat-conductive branches extending between the plurality of TTSVs.

3. The electronic device of claim 1, further comprising:
one or more anti-fuses configured to connect the one or more metallization lines as the heat-conductive branches; and
one or more fuses configured to disconnect the one or more metallization lines from carrying the active signals of the active circuitry.

4. The electronic device of claim 1, further comprising:
a set of one or more nanoelectromechanical system (NEMS) switches having a first switch state in which the first set of one or more NEMS switches is configured to connect the one or more metallization lines as the heat-conductive branches, and a second switch state in which the first set of one or more NEMS switches is configured to remove the one or more metallization lines as the heat-conductive branches.

5. The electronic device of claim 1, wherein:
the first mode of operation of the active circuitry is a diagnostic mode of operation of the active circuitry; and
the second mode of operation of the active circuitry is a normal mode of operation of the active circuitry.

6. The electronic device of claim 1, wherein:
the first mode of operation of the active circuitry is a normal mode of operation of the active circuitry; and
the second mode of operation of the active circuitry is associated one or more portions of the active circuitry being in a quiescent state.

7. The electronic device of claim 6, wherein:
the one or more metallization lines carry active signals associated with the one or more portions of the active circuitry when the active circuitry is in the first mode of operation and do not carry active signals associated with the one or more portions of the active circuitry when the active circuitry is in the second mode of operation.

8. The electronic device of claim 1, wherein:
the one or more substrates comprise a plurality of stacked substrates;
the one or more TTSVs extend through the plurality of stacked substrates to form the first set of one or more thermally conductive paths; and
the first set of one or more thermally conductive paths includes at least one thermally conductive path between each substrate of the plurality of stacked substrates and the heat sink structure.

9. The electronic device of claim 1, wherein the electronic device comprises at least one of:
a music player;
a video player;
an entertainment unit;
a navigation device;
a communications device;
a mobile device;
a mobile phone;
a smartphone;
a personal digital assistant;
a fixed location terminal;
a tablet computer, a computer;
a wearable device;
a laptop computer;
a server;
an internet of things (IoT) device; or
a device in an automotive vehicle.

10. A thermal dissipation structure, comprising:
a heat sink structure disposed exterior to one or more substrates with active circuitry;
one or more thermal through-substrate vias (TTSVs) forming a first set of one or more thermally conductive paths between the one or more substrates and the heat sink structure; and
one or more metallization lines disposed in the one or more substrates, wherein
in a first mode of operation of the active circuitry, the one or more metallization lines carry active signals of the active circuitry, and
in a second mode of operation of the active circuitry, the one or more metallization lines do not carry active signals of the active circuitry and the one or more metallization lines are connected as heat-conductive branches forming a second set of one or more thermally conductive paths in thermal contact with the first set of one or more thermally conductive paths.

11. The thermal dissipation structure of claim 10, wherein:
the one or more TTSVs comprise a plurality of TTSVs; and
the second set of one or more thermally conductive paths are placed in thermal contact with the first set of one or more thermally conductive paths through one or more permanent heat-conductive branches extending between the plurality of TTSVs.

12. The thermal dissipation structure of claim 10, further comprising:
one or more anti-fuses configured to connect the one or more metallization lines as the heat-conductive branches; and
one or more fuses configured to disconnect the one or more metallization lines from carrying the active signals of the active circuitry.

13. The thermal dissipation structure of claim 10, further comprising:
a set of one or more nanoelectromechanical system (NEMS) switches having a first switch state in which the first set of one or more NEMS switches is configured to connect the one or more metallization lines as the heat-conductive branches, and a second switch state in which the first set of one or more NEMS switches is configured to disconnect the one or more metallization lines from functioning as the heat-conductive branches.

14. The thermal dissipation structure of claim 10, wherein:
the first mode of operation of the active circuitry is a diagnostic mode of operation of the active circuitry; and
the second mode of operation of the active circuitry is a normal mode of operation of the active circuitry.

15. The thermal dissipation structure of claim 10, wherein:
the first mode of operation of the active circuitry is a normal mode of operation of the active circuitry; and
the second mode of operation of the active circuitry is associated one or more portions of the active circuitry being in a quiescent state.

16. The thermal dissipation structure of claim 15, wherein:
the one or more metallization lines carry active signals associated with the one or more portions of the active circuitry when the active circuitry is in the first mode of operation and do not carry active signals associated with the one or more portions of the active circuitry when the active circuitry is in the second mode of operation.

17. The thermal dissipation structure of claim 10, wherein:
the one or more substrates comprise a plurality of stacked substrates;
the one or more TTSVs extend through the plurality of stacked substrates to form the first set of one or more thermally conductive paths; and
the first set of one or more thermally conductive paths includes at least one thermally conductive path between each substrate of the plurality of stacked substrates and the heat sink structure.

18. The thermal dissipation structure of claim 10, wherein the heat sink structure comprises:
a heat spreader;
a heat sink; or
a combination thereof.

19. A method of operating a thermal dissipation structure to dissipate heat generated by active circuitry of one or more substrates, the method comprising:
providing one or more thermal through-substrate vias (TTSVs) through at least one substrate of the one or more substrates to form a first set of one or more thermally conductive paths between the at least one substrate of the one or more substrates and a heat sink structure;
in a first mode of operation of the active circuitry, configuring one or more metallization lines of the at least one substrate to carry active signals of the active circuitry; and
in a second mode of operation of the active circuitry in which the one or more metallization lines do not carry active signals of the active circuitry, connecting the one or more metallization lines as heat-conductive branches to the one or more TTSVs as thermally conductive lines and disconnecting the one or more metallization lines from operating as signal carrying lines.

20. The method of claim 19, further comprising:
actuating one or more anti-fuses to connect the one or more metallization lines as the heat-conductive branches; and
actuating one or more fuses to disconnect the one or more metallization lines from carrying the active signals of the active circuitry.
